(19) United States
(12) Patent Application Publication
(10) Pub. No.: US 2009/0067991 A1
(43) Pub. Date: Mar. 12, 2009

(54) COOLING FAN

(75) Inventors: CHING-BAI HWANG, Tu-Cheng (TW); ZHI-HUI ZHAO, Shenzhen (CN); JIE ZHANG, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 11/959,263

(22) Filed: Dec. 18, 2007

(30) Foreign Application Priority Data
Sep. 7, 2007 (CN) 200710077021.3

(51) Int. Cl. F04D 29/66; H05K 7/20

(52) U.S. Cl. 415/119; 415/203; 415/214.1; 361/695

(57) ABSTRACT

A cooling fan (100) includes a housing (50) and an impeller (20) rotatably received in the housing. The housing includes a bottom base (52) and a top cover board (59). The impeller includes a plurality of fan blades (25). A bump (58) extends upwardly from the base and surrounds a portion of an outer periphery of the impeller for blocking a portion of an airflow generated by the impeller and rebounded from the housing from entering the fan blades via a bottom of the fan blades.

### BACKGROUND OF THE INVENTION

1. Field of the Invention

The present invention relates generally to a cooling fan, and more particularly relates to a cooling fan having an improved housing for lowering noise level generated by the fan when the fan is operated.

2. Description of Related Art

With continuing development of the electronic technology, electronic packages such as CPUs (central processing units) are generating more and more heat, which requires immediate dissipation. Cooling fans are commonly used in combination with heat sinks for cooling CPUs.

A related cooling fan 90, as shown in FIG. 6, generally includes a plurality of fan blades 92 received in a fan housing 95. The fan housing 95 includes a sidewall 950, and a cover 951 and a base 953 as top and bottom walls for enclosing free end portions of the fan blades 92. An high-pressured airflow generated by the fan blades 92 accumulates in a room 94 among the cover 951, the base 953, the sidewall 950 and an outer periphery of the fan blades 92. The high-pressured airflow impinges on the sidewall 950, the cover 951 and the base 953, and then a portion of the airflow will rebound and flow back into the fan blades 92, as indicated by arrows in FIG. 6. Since there is a large gap between the base 953 and the fan blades 92, a portion of the airflow will rebound from the base 953 and flow upwardly toward the fan blades 92 via a bottom thereof. Such an upwardly rebounded airflow causes the rotating fan blades 92 to generate a large level of noise.

For the foregoing reasons, there is a need for a cooling fan which can reduce noise generated when the cooling fan is operated.

### SUMMARY OF THE INVENTION

A cooling fan includes a housing and an impeller rotatably received in the housing. The housing includes a bottom base and a top cover board. The impeller includes a plurality of fan blades. When the impeller rotates, the fan blades generate a high-pressured airflow. A bump extends upwardly from the base and located between a sidewall of the housing and the fan blades of the impeller. The bump is provided for blocking a portion of the airflow rebounded from the base of the housing outside the bump from entering the fan blades via a bottom of the fan blades. By the provision of the bump, the noise level generated by the impeller when it rotates can be lowered.

Other advantages and novel features of the present invention will become more apparent from the following detailed description of preferred embodiment when taken in conjunction with the accompanying drawings, in which:

### BRIEF DESCRIPTION OF THE DRAWINGS

Many aspects of the present cooling fan can be better understood with reference to the following drawings. The components in the drawings are not necessarily drawn to scale, the emphasis instead being placed upon clearly illustrating the principles of the present cooling fan. Moreover, in the drawings, like reference numerals designate corresponding parts throughout the several views.

FIG. 1 is an isometric, assembled view of a cooling fan in accordance with a preferred embodiment of the present invention;

FIG. 2 is an isometric, exploded view of the cooling fan of FIG. 1;

FIG. 3 is an enlarged view of a shell of the cooling fan of FIG. 1;

FIG. 4 is a cross sectional view of the cooling fan of FIG. 1;

FIG. 5 is a cross sectional view of a cooling fan in accordance with a second embodiment of the present invention; and

FIG. 6 is a cross sectional view of a cooling fan in accordance with related art.

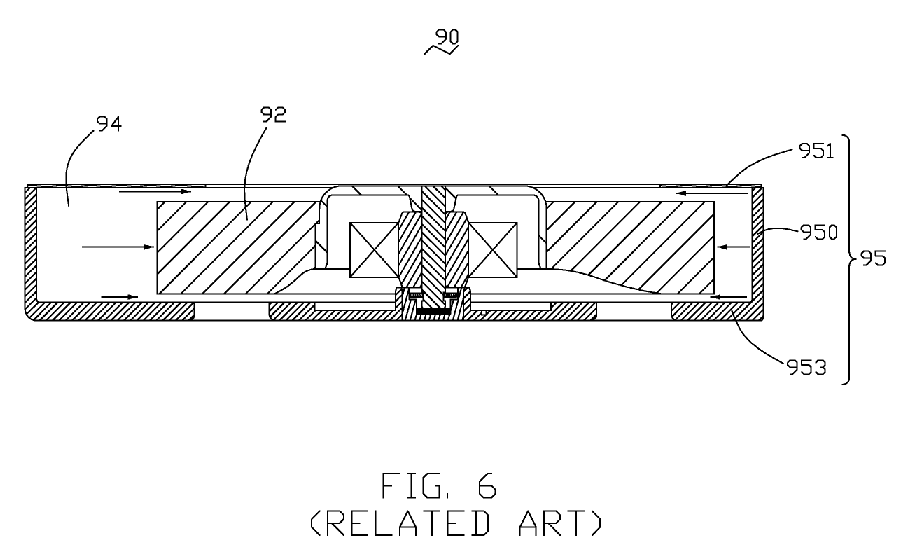

### DETAILED DESCRIPTION OF THE INVENTION

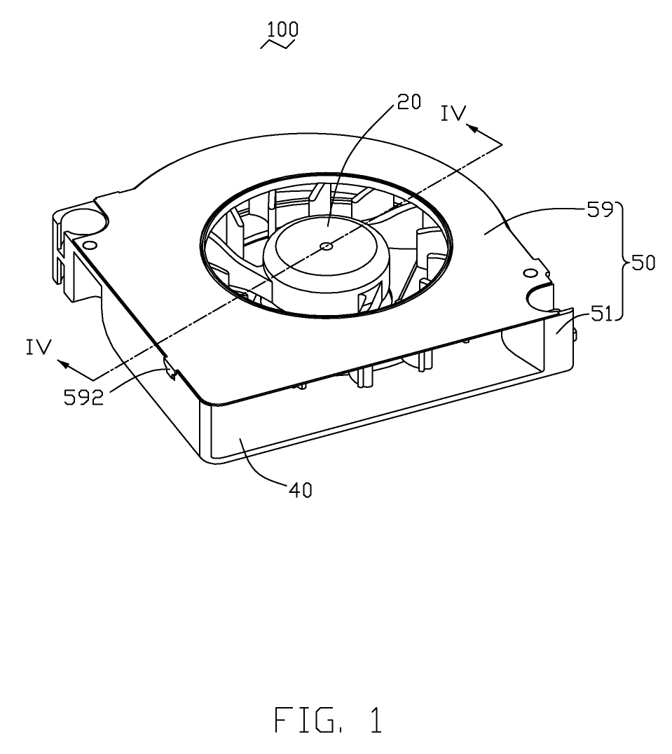

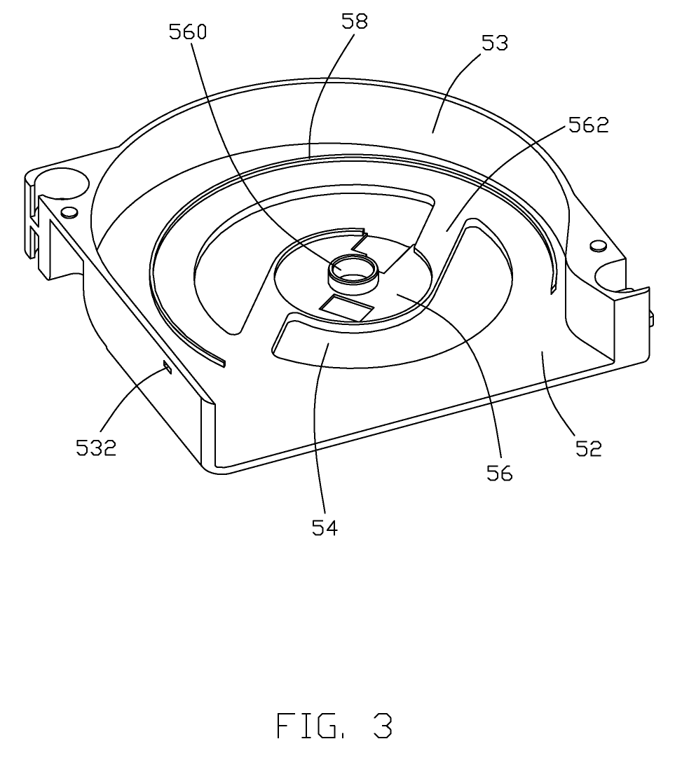

Referring to FIGS. 1-3, a cooling fan 100 in accordance with a preferred embodiment of the present invention is shown. The cooling fan 100 can be used in combination with a heat dissipation device (not shown) to cool heat-generating electronic components such as CPUs. The cooling fan 100 comprises a housing 50 and an impeller 20 rotatably received in the housing 50.

The housing 50 has a shell 51 and a cover board 59 mounted on the shell 51. The shell 51 defines a recess (not labeled) with opened top side and front side. The shell 51 comprises a bottom base 52 and a side wall 53 extending upwardly from an outer edge of the base 52. The base 52 defines two arc-shaped holes 54 in a center portion thereof. A circular seat 56 connecting with the base 52 by two arms 562 is located between the two holes 54 and surrounded by the holes 54. A tube 560 extends upwardly from a central portion of the circular seat 56. An arc-shaped bump 58 extends upwardly from a top surface 526 of the base 52. The bump 58 is located around the holes 54 and is used to encircle the impeller 20. The base 52 has an arc-shaped edge 521 and two straight edges 523, 524 perpendicular to each other. The side wall 53 extends upwardly from the arc-shaped edge 521 and the straight edge 523. The bump 58 is spaced from the side wall 53 and defines an opening (not labeled) opened to the straight edge 524. A width of the bump 58 is approximately 0.4 mm. The side wall 53 defines two cavities 532 (only one shown) in two opposite lateral sides thereof, respectively; the two cavities 532 are adjacent to a top portion of the side wall 53. The cover board 59 has a contour similar to the top portion of the side wall 53 and defines a central hole 590 in a middle thereof. Two clasps 592 are formed downwardly in two opposite sides of the cover board 59 corresponding to the cavities 532 of the side wall 53. The clasps 592 are used to engage in the cavities 532 to secure the cover board 59 to the side wall 53 of the shell 51. Thus, the shell 51 and the cover board 59 cooperatively define a space 40 therebetween for receiving the impeller 20 therein, and the space 40 communicates with external environment via a front side of the housing 50, which is coincident with the opened front side of the shell 51. The front side of the housing 50 functions as an outlet of the fan.

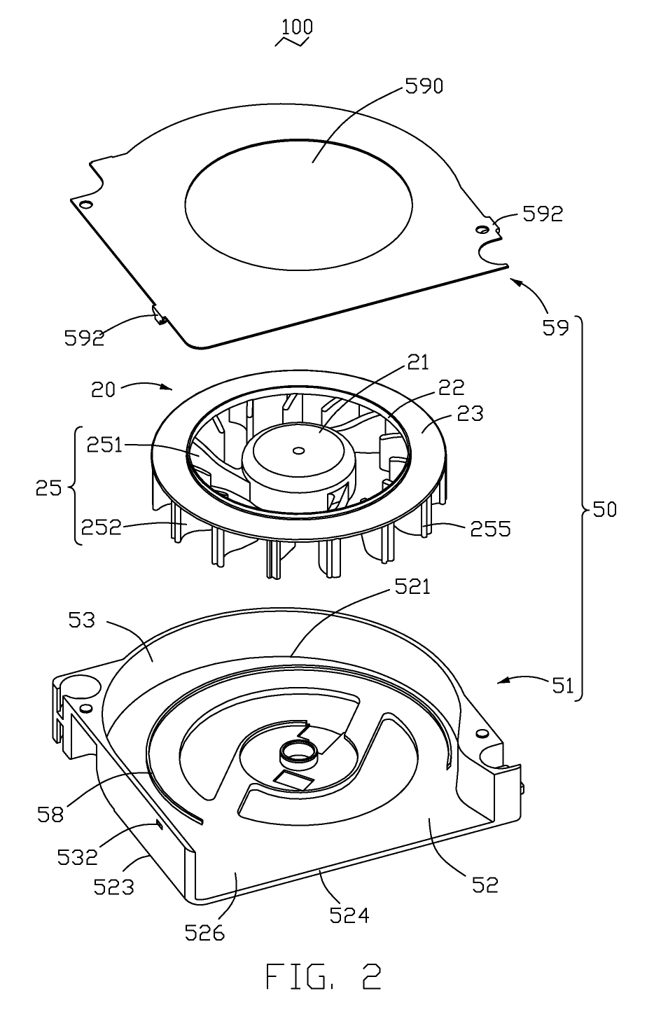

The impeller 20 comprises a hub 21 and a plurality of fan blades 25 radially formed around the hub 21. The fan blades 25 comprise three first blades 251 evenly extending outwardly from an outer periphery of the hub 21 and a plurality of second blades 252 located between every two adjacent first blades 251. An annular plate 23 locating around the hub 21 is attached to a top portion of a peripheral part of each of the first blades 251. Top portions of the second blades 252 are attached to a bottom surface of the annular plate 23. An annular bulge 22 extends upwardly from an inner edge of the annular plate 23. A width of the bulge 22 is approximately 0.3 mm. Each of the fan blades 25 comprises a ledge 255 extending laterally from an outmost end thereof. An extension length of the ledge 255 is in a range of 0.6 mm to 0.8 mm. The ledges 255 bend in a counterclockwise direction as viewed from FIG. 2 and form discontinuous, obstructed walls in a periphery of the impeller 20. The hub 21 includes a shaft (not labeled) extending downwards therefrom. A bearing (not labeled) is received in the central tube 56. The impeller 20 is rotatably secured to the shell 51 via the shaft rotatably engaging in the bearing of the hub 21.

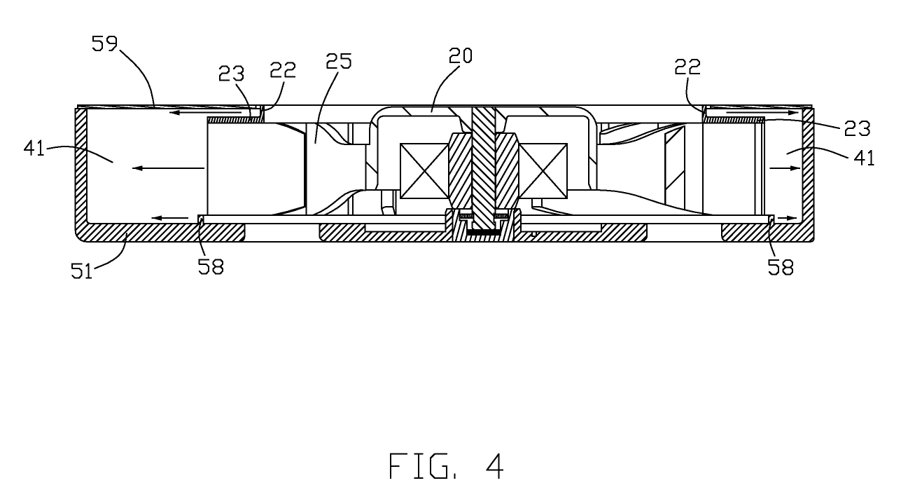

Also referring to FIG. 4, when assembled, a top surface of the bump 58 is located at a same horizontal level with a bottom surface of the fan blades 25. The annular bulge 22 extends into the central hole 590. A top surface of the annular bulge 22 is located at a same horizontal level with a top surface of the cover board 59. A distance between each of the outmost ends of the fan blades 25 and an inner surface of the bump 58 is approximately 0.3 mm. A distance between an outer surface of the annular bulge 22 and an inner surface of the cover board 59 defining the central hole 590 is approximately 0.4 mm. A distance between a bottom surface of the cover board 59 and a top surface of the annular plate 23 is in a range of 0.6 mm to 0.7 mm. When the impeller 20 rotates, a high-pressured airflow is generated in a room 41 among the side wall 53, the cover board 59, the base 52 and an outer periphery of the fan blades 25. By the provision of the bump 58, a portion of the high-pressured airflow in the room 41 and rebounded from a portion of the base 52 of the shell 51 outside the bump 58 is prevented by the bump 58 from flowing back into the fan blades 25 via a bottom thereof, whereby noise generated by the fan when the fan is operated is lowered. Moreover, by the provision of the annular bulge 22 which blocks a portion of the high-pressured airflow rebounded from the housing 50 from entering upper parts of the fan blades 25, the noise level generated during the operation of the fan can be further lowered.

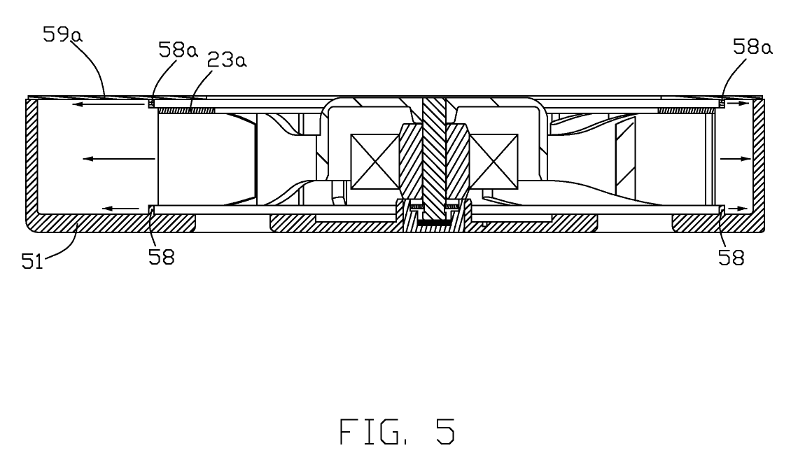

FIG. 5 shows a cross sectional view of a cooling fan in accordance with a second embodiment of the present invention. In this embodiment, a second bump 58a is provided to substitute for the annular bulge 22 of the annular plate 23 of the first embodiment, for blocking the portion of the high-pressured airflow rebounded from the housing 50 from entering the upper parts of the fan blades 25. The second bump 58a extends downwardly from a bottom surface of the cover board 59a towards the first bump 58 provided on the base 52 of the shell 51. The second bump 58a is in line with the first bump 58 and has a bottom face located at a same horizontal level with a top face of the annular plate 23.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A cooling fan comprising:
a housing including a bottom base plate and a top cover plate;
an impeller rotatably received in the housing and comprising a plurality of fan blades,
a room being formed between an outer periphery of the fan blades and the housing; and
at least a bump extending from one of the base plate and the cover plate towards the other one of the base plate and the cover plate, the at least a bump being located around outmost free ends of the fan blades to block a portion of an airflow in the room and rebounded from a portion of the housing from flowing back to the fan blades of the impeller.

2. The cooling fan as described in claim 1, wherein the at least a bump has a height sufficiently to stop the airflow in the room and rebounded from the portion of the housing from flowing back to a space formed between the fan blades of the impeller and one of the base plate and the cover plate.

3. The cooling fan as described in claim 1, wherein the at least a bump extends upwardly from a top surface of the base plate towards the cover plate.

4. The cooling fan as described in claim 3, wherein a top surface of the at least a bump is located in a same horizontal level with a bottom surface of the fan blades of the impeller.

5. The cooling fan as described in claim 1, wherein the at least a bump extends downwardly from a bottom surface of the cover plate towards the base plate.

6. The cooling fan as described in claim 1, wherein the at least a bump includes a first bump extending upwardly from a top surface of the base plate towards the cover plate and a second bump extending downwardly from a bottom surface of the cover plate towards the base plate.

7. The cooling fan as described in claim 1, wherein each of the fan blades comprises a ledge protruding laterally from an outmost free end of the each of the fan blades.

8. A cooling fan comprising:
a housing comprising a base plate, a cover board and a side wall interconnecting the base plate and the cover board;
an impeller rotatably received in the housing and comprising a plurality of fan blades, a room being formed among an outer periphery of the fan blades and the base plate, the cove board and the side wall of the housing, an annular plate being located adjacent to the cover board and attached to the fan blades, an annular bulge extending upwardly from an edge of the annular plate into a hole defined in the cover board, the annular bulge being located neighboring an inner face of the cover board defining the hole to block a portion of an airflow in the room and generated by the fan blades from flowing back to the fan blades of the impeller; and
a bump extending upwardly from the base plate, the bump being located around outmost free ends of the fan blades to block another portion of the airflow in the room from flowing back to the fan blades of the impeller.

9. The cooling fan as described in claim 8, wherein the bump has an arc-shaped configuration.

10. The cooling fan as described in claim 8, wherein the impeller has a central hub, some of the fan blades connecting with the central hub.

11. The cooling fan as described in claim 10, wherein a top surface of the bump is located in a same horizontal level with bottom surfaces of the fan blades.

12. The cooling fan as described in claim 10, wherein a top surface of the annular bulge is located in a same horizontal level with a top surface of the cover board.

13. The cooling fan as described in claim 8, wherein each of the fan blades comprises a ledge protruding laterally from an outmost end of the each of the fan blades.

14. The cooling fan as described in claim 8, wherein the airflow leaves the fan via a side opening defined among the cove board, the side wall and the base plate.

15. A cooling fan comprising:
a housing having a shell with a base and a side wall extending upwardly from the base and a cover plate mounted on a top end of the side wall of the shell;
an impeller rotatably mounted in a space defined between the shell and the cover plate, the impeller having a hub and a plurality fan blades extending outwardly from the hub, each fan blade having a bottom spaced from the base a distance;
wherein the base has a bump extending upwardly from the base and located at a position between the side wall and the fan blades, for blocking a portion of an airflow generated by the impeller and rebounded from a portion of the base outside the bump from entering the each fan blade via the bottom thereof.

16. The cooling fan as described in claim 15, wherein the bump has an arc-shaped configuration surrounding a portion of an outer periphery of the impeller.

17. The cooling fan as described in claim 16, wherein the impeller has an annular plate connecting a top of each fan blade, the annular plate having an annular bulge extending upwardly into a hole defined in the cover plate and neighboring an inner face of the cover plate defining the hole.

18. The cooling fan as described in claim 17, wherein the annular bulge has a top surface located at a same horizontal level with a top surface of the cover plate.

19. The cooling fan as described in claim 15, wherein the cover plate forms an additional bump extending downwardly at a position corresponding to the bump at the base.

20. The cooling fan as described in claim 15, wherein the bump at the base has a top surface located at a same horizontal level with the bottom of the each fan blade.
